(19) United States
(12) Patent Application Publication
(10) Pub. No.: US 2025/0133884 A1
(43) Pub. Date: Apr. 24, 2025

(54) LIGHT-EMITTING DEVICE

(71) Applicant: NICHIA CORPORATION, Anan-shi (JP)

(72) Inventors: Takayuki SOGO, Tokushima-shi (JP); Hiroshi MARUYAMA, Suwa-gun (JP); Hiroyuki KITAOKA, Anan-shi (JP); Yusuke MONJI, Anan-shi (JP)

(21) Appl. No.: 18/920,602

(22) Filed: Oct. 18, 2024

(30) Foreign Application Priority Data
Oct. 19, 2023 (JP) 2023-180215

(51) Int. Cl. H01L 33/58

(52) U.S. Cl. CPC H10H 20/855

(57) ABSTRACT

A light-emitting device includes: a base having an upper surface; a lid body having an upper surface and a lower surface bonded to the base; and a lens member having a lower surface bonded to the lid body. An outer edge of the upper surface of the base has first and second sides parallel to each other. An outer edge of the lower surface of the lid body has first and second sides parallel to each other. In a top view, a distance from the second side of the base to the second side of the lid body is greater than a distance from the first side of the base to the first side of the lid body. A distance from the first side of the lid body to a lens surface is smaller than a distance from the second side of the lid body to the lens surface.

### CROSS-REFERENCE TO RELATED APPLICATIONS

This application claims priority to Japanese Patent Application No. 2023-180215 filed on Oct. 19, 2023, the disclosure of which is hereby incorporated herein by reference in its entirety.

### BACKGROUND

The present invention relates to a light-emitting device. Japanese Patent Publication No. 2021-97216 discloses a light-emitting device including a package including a base portion and a lid member to be bonded to the base portion, a semiconductor laser element, and an optical member to be bonded to the lid member.

### SUMMARY

One aspect of the present disclosure is directed to provide a light-emitting device with improved production efficiency.

Alternatively, another aspect of the present disclosure is directed to provide a light-emitting device with reduced weight.

Alternatively, another aspect of the present disclosure is directed to achieve a package having a stable bonding balance between a base and a lid body.

Alternatively, another aspect of the present disclosure is directed to achieve stable bonding processing in the manufacture of a light-emitting device.

In the present specification, a disclosure also discloses an invention for solving a plurality of the above-described aspects in combination.

A light-emitting device disclosed in an embodiment includes a base, a lid body, one or more light-emitting elements, and a lens member. The base includes a base portion having a first upper surface, and a frame portion having a second upper surface positioned above the first upper surface and surrounding the first upper surface in a top view. The lid body has an upper surface and a lower surface bonded to the second upper surface of the base. One or more light-emitting elements is disposed on the first upper surface of the base. The lens member has a lower surface bonded to the upper surface of the lid body. An outer edge shape of the second upper surface of the base is a rectangle having a first side and a second side parallel to the first side in the top view. An outer edge shape of the lower surface of the lid body is a rectangle having a first side parallel to the first side of the base and a second side parallel to the first side of the lid body in the top view. The first side of the lid body is disposed closer to the first side of the base than the second side of the lid body. The second side of the lid body is disposed closer to the second side of the base than the first side of the lid body. In the top view, a shortest distance from the second side of the base to the second side of the lid body is greater than a shortest distance from the first side of the base to the first side of the lid body. The lens member includes a lens portion having one or more lens surfaces and a non-lens portion not overlapping the one or more lens surfaces in the top view. In the top view, a shortest distance from the first side of the lid body to the one or more lens surfaces is smaller than a shortest distance from the second side of the lid body to the one or more lens surfaces. In the top view, a maximum width of the one or more lens surfaces is 65% or more of a maximum width of the lens member in a direction orthogonal to the first side of the base.

In one embodiment or at least one of a plurality of embodiments, improved production efficiency of a light-emitting device can be achieved.

### BRIEF DESCRIPTION OF DRAWINGS

FIG. 1 is a perspective view of a light-emitting device according to an embodiment.

FIG. 2 is a side view of the light-emitting device according to the embodiment as viewed from a positive direction of Y.

FIG. 3 is a side view of the light-emitting device according to the embodiment as viewed from a positive direction of X.

FIG. 4 is a top view of the light-emitting device according to the embodiment.

FIG. 5 is a cross-sectional view taken along cross section line V-V in FIG. 4.

FIG. 6 is a top view for explaining a bonding state of bonding members of the light-emitting device according to the embodiment.

FIG. 7 is a perspective view for explaining components arranged in an internal space of the light-emitting device according to the embodiment.

FIG. 8 is a top view for explaining the components arranged in the internal space of the light-emitting device according to the embodiment.

FIG. 9 is a perspective view of a package according to the embodiment.

FIG. 10 is a top view of the package according to the embodiment.

FIG. 11 is a cross-sectional view taken along cross section line XI-XI in FIG. 10.

FIG. 12 is a top view of a base according to the embodiment.

FIG. 13 is a bottom view of the base according to the embodiment.

FIG. 14 is a cross-sectional view taken along cross section line XIV-XIV in FIG. 12.

FIG. 15 is a perspective view of a lid body according to the embodiment as viewed from a lower surface side.

FIG. 16 is a bottom view of the lid body according to the embodiment.

FIG. 17 is a top view for describing a state of a light-emitting element and the like mounted on a submount according to the embodiment.

FIG. 18 is a side view for explaining a state of the light-emitting element and the like mounted on the submount according to the embodiment.

### DETAILED DESCRIPTIONS

In the present specification or the claims, polygons such as triangles and quadrangles, including shapes in which the corners of the polygon are rounded, beveled, chamfered, or coved, are referred to as polygons. A shape obtained by processing not only the corners (ends of a side) but also an intermediate portion of the side is similarly referred to as a polygon. That is, a shape that is partially processed while remaining a polygon shape as a base is included in the interpretation of “polygon” described in the present description and the claims.

The same applies not only to polygons but also to words representing specific shapes such as trapezoids, circles, protrusions, and recesses. The same applies when dealing with each side forming that shape. That is, even if processing is performed on a corner or an intermediate portion of a certain side, the interpretation of “side” includes the processed portion. When a “polygon” or “side” not partially processed is to be distinguished from a processed shape, “exact” will be added to the description as in, for example, “exact quadrangle”.

Further, in the present description or the claims, descriptions such as upper and lower (upward/downward), left and right, surface and reverse, front and back (forward/backward), and near and far are used merely to describe the relative relationship of positions, orientations, and directions, and the expressions do not necessarily match an actual relationship at the time of use.

In the drawings, directions such as an X direction, a Y direction, and a Z direction may be indicated by using arrows. The directions of the arrows are consistent across multiple drawings of the same embodiment. In the drawings, the directions of the arrows marked with X, Y, and Z are the positive directions, and the opposite directions are the negative directions. For example, the direction marked with X at the tip of the arrow is the X direction and the positive direction. In the present description, the direction that is the X direction and is the positive direction will be referred to as the “positive direction of X” and the direction opposite to this will be referred to as the “negative direction of X”. The term “X direction” includes both the positive direction and the negative direction. The same applies to the Y direction and the Z direction.

In the present description, when a certain object is specified as “one or more” and the object is described, an embodiment in which the object is one and an embodiment in which the object is plural are collectively described. Thus, a description specified as “one or more” supports every case of an embodiment including one or more objects, an embodiment including at least one object, and an embodiment including a plurality of objects.

In the present description, the description illustrating “one or each” object is a description summarizing a description of one object in an embodiment including the one object, a description of one object in an embodiment including a plurality of objects, and a description of each of a plurality of objects in an embodiment including the plurality of objects. Thus, the description illustrating “one or each” object supports every case of an embodiment including one object in which the one object satisfies the described content, an embodiment including a plurality of objects in which, among these objects, at least one of the objects satisfies the described content, and an embodiment including a plurality of objects in which each of these plurality of objects satisfies the described content, and an embodiment including one or more objects in which all of the objects satisfy the described content.

The term “member” or “portion” may be used to describe, for example, a component in the present description. The term “member” refers to an object physically treated alone. The object physically treated alone can be an object treated as one part in a manufacturing process. Meanwhile, the term “portion” refers to an object that need not be physically treated alone. For example, the term “portion” is used when part of one member is partially considered, or a plurality of members are collectively considered as one object.

The distinction between “member” and “portion” described above does not indicate an intention to consciously limit the scope of right in interpretation of the doctrine of equivalents. That is, even when a component described as “member” is present in the claims, this does not mean that the applicant recognizes that physically treating the component alone is essential in the application of the present invention.

In the present description or the claims, when a plurality of components are present and these components are to be indicated separately, the components may be distinguished by adding the terms “first” and “second” at the beginning of the names of the components. Objects to be distinguished may differ between the present description and the claims. Thus, even when a component in the claims is given the same term as that in the present description, the object identified by that component is not the same across the present description and the claims in some cases.

For example, when components distinguished by being termed “first”, “second”, and “third” are present in the present description, and when components given the terms “first” and “third” in the present description are described in the claims, these components may be distinguished by being denoted as “first” and “second” in the claims for ease of understanding. In this case, the components denoted as “first” and “second” in the claims refer to the components termed “first” and “third” in the present description, respectively. This rule applies to not only components but also other objects in a reasonable and flexible manner.

An embodiment for implementing the present invention will be described below. A specific embodiment for implementing the present invention will be described below with reference to the drawings. An embodiment for implementing the present invention is not limited to the specific embodiment. That is, the embodiment illustrated by the drawings is not the only form in which the present invention is implemented. Sizes, positional relationships, and the like of members illustrated in each of the drawings may sometimes be exaggerated in order to facilitate understanding.

### Embodiment

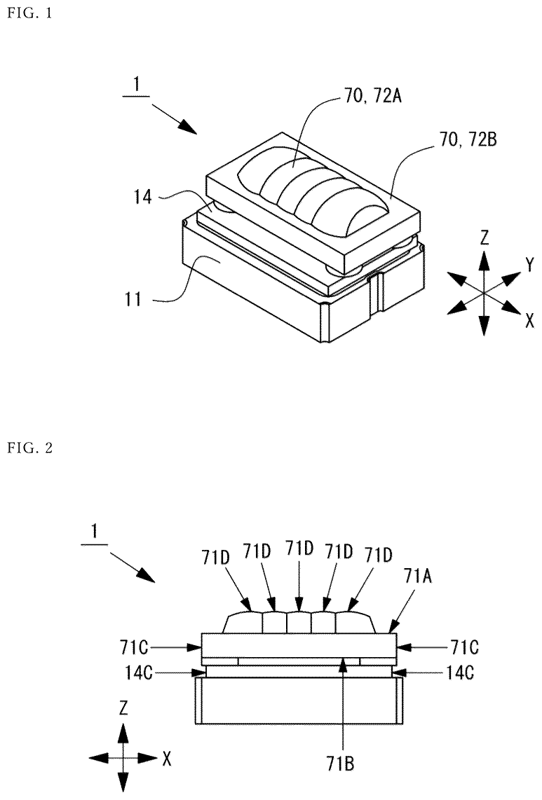

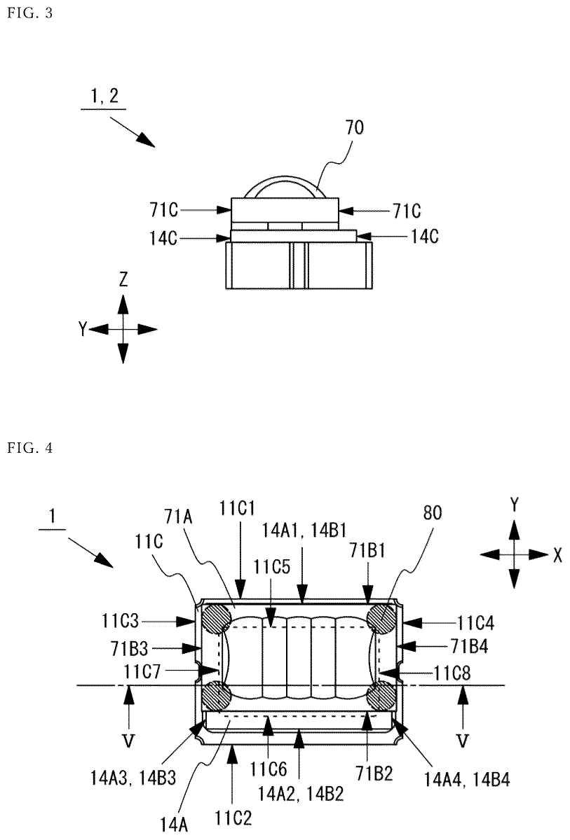

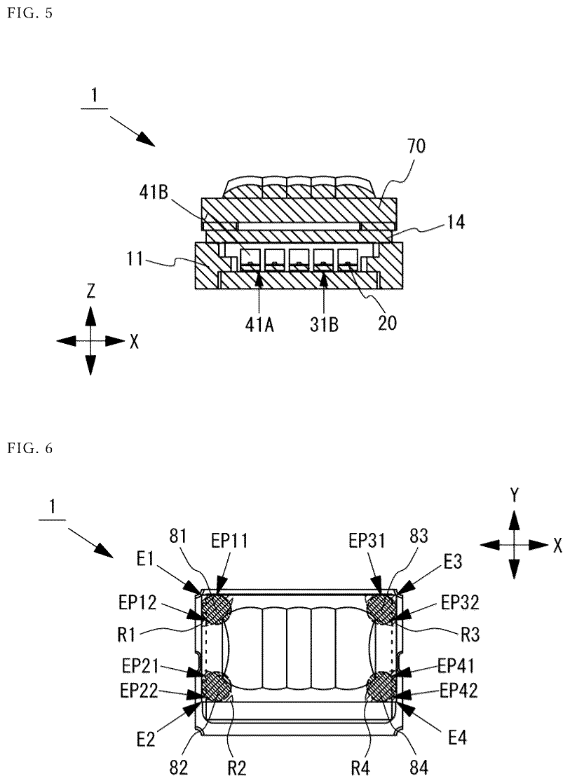

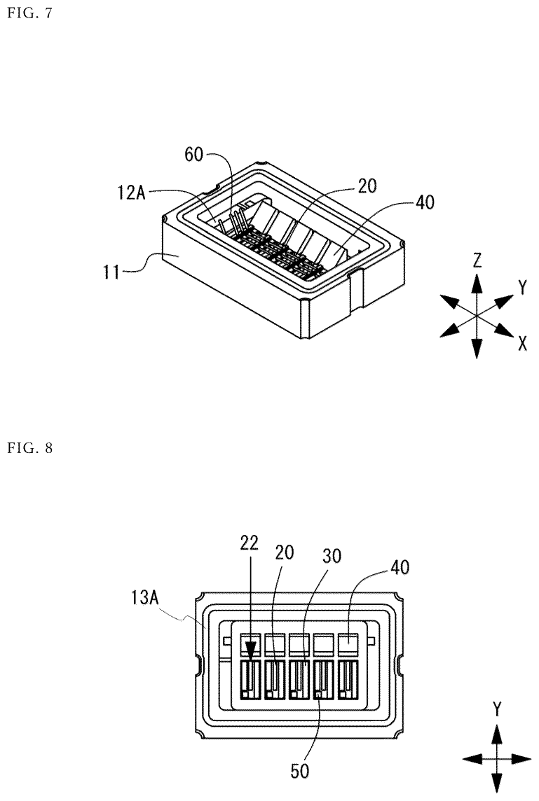

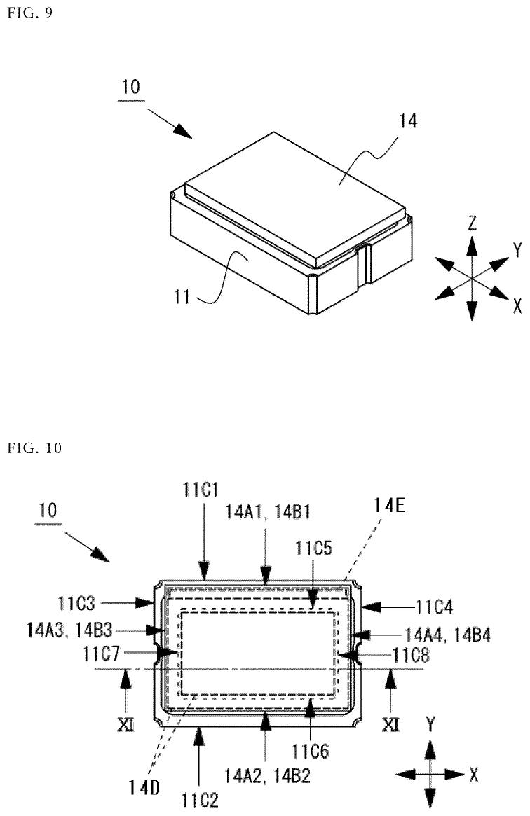

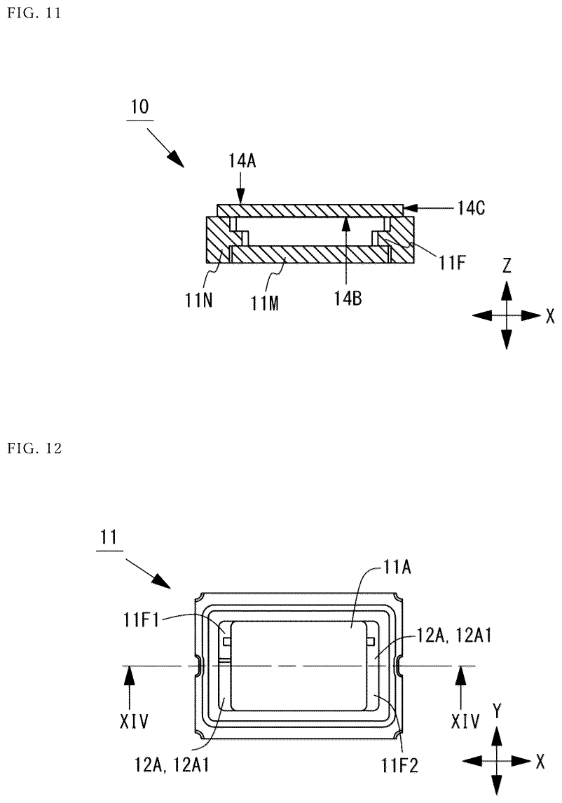

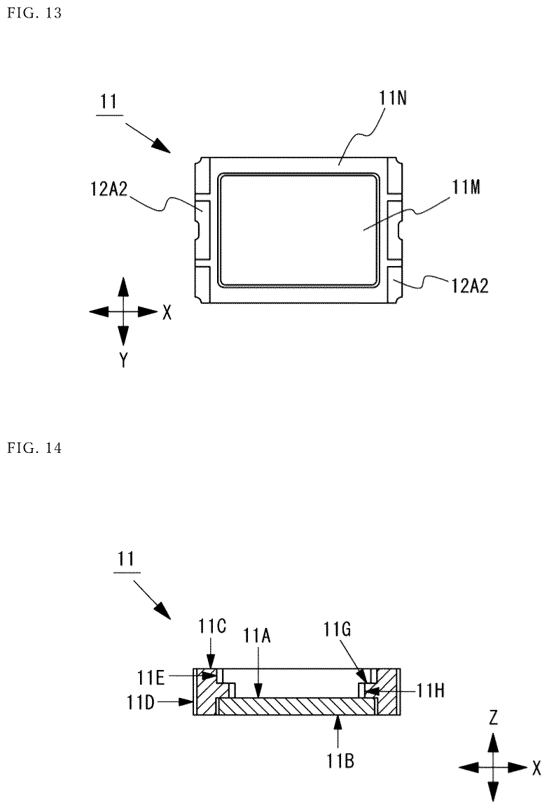

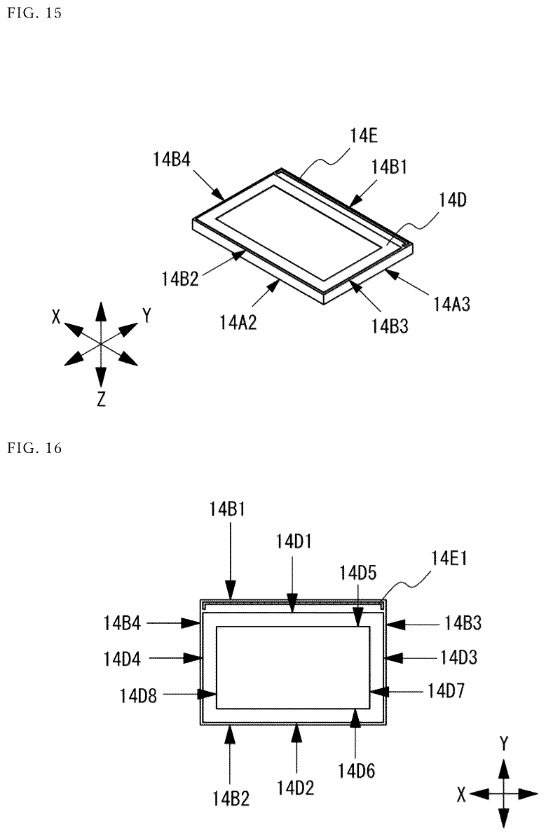

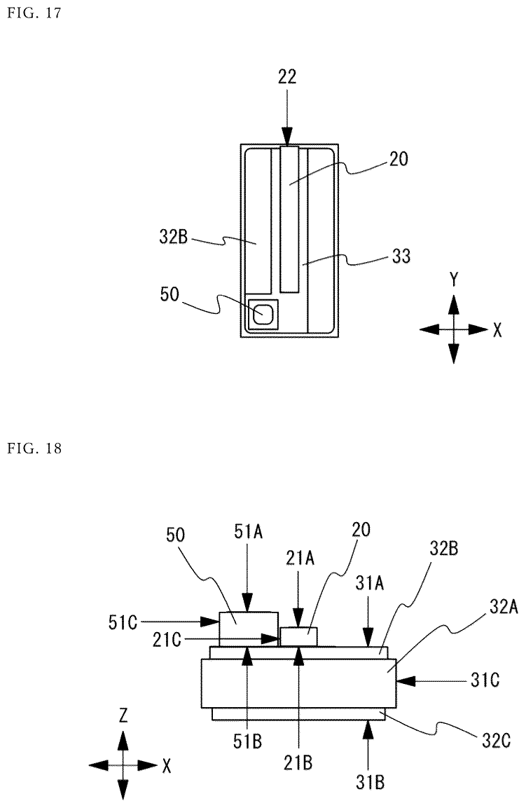

A light-emitting device 1 according to an embodiment will now be described. FIGS. 1 to 18 are views for explaining an exemplary form of the light-emitting device 1. FIG. 1 is a perspective view of the light-emitting device 1. FIG. 2 is a side view of the light-emitting device 1 as viewed from the positive direction of Y. FIG. 3 is a side view of the light-emitting device 1 as viewed from the positive direction of X. FIG. 4 is a top view of the light-emitting device 1. In FIG. 4, regions where bonding members 80 are formed are indicated by hatching surrounded by a dashed line. An inner frame of a second upper surface 11C of a base 11 is indicated by a dotted line. FIG. 5 is a cross-sectional view of the light-emitting device 1 taken along cross section line V-V in FIG. 4. FIG. 6 is a top view for explaining a bonding state of bonding members 80 of the light-emitting device 1. In FIG. 6, a first region R1 to a fourth region R4 are indicated by hatching in a direction different from that of a first bonding member 81 to a fourth bonding member 84. A portion that is an outer edge of an upper surface 14A of a lid body 14 and overlaps an optical member 70 in a top view is indicated by a dotted line. FIGS. 7 and 8 are a perspective view and a top view for explaining components arranged in an internal space of the light-emitting device 1. In FIG. 8, wiring lines 60 illustrated in FIG. 7 are omitted. FIG. 9 is a perspective view of a package 10. FIG. 10 is a top view of the package 10. In FIG. 10, the inner frame of the second upper surface 11C of the base 11 is indicated by a dotted line, and a bonding pattern 14D and a buffer line pattern 14E of the lid body 14 are indicated by dashed lines. FIG. 11 is a cross-sectional view of the package 10 taken along cross section line XI-XI in FIG. 10. FIG. 12 is a top view of the base 11. FIG. 13 is a bottom view of the base 11. FIG. 14 is a cross-sectional view of the base 11 view taken along cross section line XIV-XIV in FIG. 12. FIG. 15 is a perspective view of the lid body 14 as viewed from a lower surface 14B side. FIG. 16 is a bottom view of the lid body 14. In FIG. 16, a buffer line 14E1 is indicated by hatching. FIGS. 17 and 18 are a top view and a side view for explaining a state of a light-emitting element 20 and the like mounted on a submount 30.

The light-emitting device 1 includes a plurality of components. The plurality of components include the package 10, one or more of the light-emitting elements 20, one or more of the submounts 30, one or more reflective members 40, one or more protective elements 50, a plurality of the wiring lines 60, the optical member 70, and one or more of the bonding members 80.

The light-emitting device 1 may include a component other than the components described above. For example, the light-emitting device 1 may further include a light-emitting element different from the one or more light-emitting elements 20. The light-emitting device 1 need not include some of the components described above.

Firstly, each of the components will be described.

### Package 10

The package 10 includes the base 11 and the lid body 14. The lid body 14 is bonded to the base 11 to form the package 10. An internal space in which other components are disposed is defined in the package 10. The internal space is a closed space surrounded by the base 11 and the lid body 14. The internal space can also be a sealed space in a vacuum or airtight state.

An outer edge shape of the package 10 in a top view is rectangular. This rectangle can be a rectangle with long sides and short sides. In the illustrated package 10, the long-side direction of the rectangle is the same direction as the X direction, and the short-side direction of the rectangle is the same direction as the Y direction. The outer edge shape of the package 10 in a top view need not be rectangular.

The internal space in which other components are disposed is formed in the package 10. A first upper surface 11A of the package 10 is a part of a region defining the internal space. Inner lateral surfaces 11E and the lower surface 14B of the package 10 are a part of the region defining the internal space.

The base 11 has the first upper surface 11A and a lower surface 11B. The base 11 has the second upper surface 11C. The base 11 has one or more outer lateral surfaces 11D. The base 11 has one or more of the inner lateral surfaces 11E. The one or more outer lateral surfaces 11D meet the second upper surface 11C. The one or more outer lateral surfaces 11D meet the lower surface 11B. The one or more inner lateral surfaces 11E meet the second upper surface 11C.

An outer edge shape of the base 11 in a top view is rectangular. The outer edge shape of the base 11 in a top view is the outer edge shape of the package 10. An outer edge shape of the first upper surface 11A in a top view is rectangular. This rectangle can be a rectangle with long sides and short sides. The long-side direction of the first upper surface 11A is parallel to the long-side direction of the outer edge shape of the base 11. The outer edge shape of the first upper surface 11A in a top view need not be rectangular.

In a top view, the first upper surface 11A is surrounded by the second upper surface 11C. The second upper surface 11C is an annular surface surrounding the first upper surface 11A in a top view. The second upper surface 11C is a surface having a rectangular and annular shape. Here, a frame defined by an inner edge of the second upper surface 11C is referred to as an inner frame of the second upper surface 11C, and a frame defined by an outer edge of the second upper surface 11C is referred to as an outer frame of the second upper surface 11C.

An outer edge shape of the second upper surface 11C is rectangular. This rectangle can include long sides and short sides. This rectangle includes a first side 11C1, a second side 11C2, a third side 11C3, and a fourth side 11C4. The second side 11C2 is parallel to the first side 11C1. The third side 11C3 is orthogonal to the first side 11C1. The fourth side 11C4 is parallel to the third side 11C3. The first side 11C1 is a long side of this rectangle.

An inner edge shape of the second upper surface 11C is rectangular. This rectangle can include long sides and short sides. This rectangle includes a first side 11C5, a second side 11C6, a third side 11C7, and a fourth side 11C8. The second side 11C6 is parallel to the first side 11C5. The third side 11C7 is orthogonal to the first side 11C5. The fourth side 11C8 is parallel to the third side 11C7. The first side 11C5 is a long side of this rectangle. For convenience, a side of the rectangle of the outer edge shape and a side of the rectangle of the inner edge shape are referred to as an outer edge side and an inner edge side, respectively, to be distinguished from each other.

The base 11 includes a recessed portion surrounded by the frame formed by the second upper surface 11C. The recessed portion defines a portion recessed downward from the second upper surface 11C in the base 11. The first upper surface 11A is a part of the recessed portion. The one or more inner lateral surfaces 11E are a part of the recessed portion. The second upper surface 11C is located above the first upper surface 11A.

The base 11 includes one or more step portions 11F. Each of the step portions 11F has an upper surface 11G and a lateral surface 11H that meets the upper surface 11G and extends downward from the upper surface 11G. Here, one step portion 11F has only one upper surface 11G and only one lateral surface 11H. The upper surface 11G meets the inner lateral surface 11E. The lateral surface 11H meets the first upper surface 11A.

One or each of the step portions 11F is formed on an inner side of the inner frame of the second upper surface 11C in a top view. One or each of the step portions 11F is formed along a part of or the entire inner lateral surface 11E in a top view. In the base 11, the lateral surface 11H is an inner lateral surface, but the lateral surface 11H and the inner lateral surface 11E are different surfaces. One or each of the inner lateral surfaces 11E and one or each of the lateral surfaces 11H are orthogonal to the first upper surface 11A. The term “orthogonal” used here allows for a difference within ±3 degrees.

The one or more step portions 11F can include a first step portion 11F1 and a second step portion 11F2. The first step portion 11F1 and the second step portion 11F2 are provided at positions where the respective lateral surfaces 11H are opposed to each other. The first step portion 11F1 and the second step portion 11F2 are provided on sides of the short sides of the inner frame of the second upper surface 11C.

The base 11 includes a base portion 11M and a frame portion 11N. The base portion 11M and the frame portion 11N may be members made of mutually different materials. The base 11 can include a base member corresponding to the base portion 11M and a frame member corresponding to the frame portion 11N.

The base portion 11M includes the first upper surface 11A. The frame portion 11N includes the second upper surface 11C. The frame portion 11N includes the one or more outer lateral surfaces 11D and the one or more inner lateral surfaces 11E. The frame portion 11N includes the one or more step portions 11F.

A lower surface of the base portion 11M constitutes a part or the entire region of the lower surface 11B of the base 11. When the lower surface of the base portion 11M constitutes a part of the region of the lower surface 11B of the base 11, a lower surface of the frame portion 11N constitutes the remaining region of the lower surface 11B of the base 11.

The base 11 includes a plurality of wiring portions 12A. The plurality of wiring portions 12A include one or more first wiring portions 12A1 arranged in the internal space of the package 10 and one or more second wiring portions 12A2 provided on an outer surface of the package 10.

One or each of the first wiring portions 12A1 is provided on the upper surface 11G of the step portion 11F. The base 11 includes the one or more first wiring portions 12A1 provided on the upper surface 11G of the first step portion 11F1. The base 11 includes the one or more first wiring portions 12A1 provided on the upper surface 11G of the second step portion 11F2.

One or each of the second wiring portions 12A2 is provided on the lower surface 11B of the package 10. One or each of the second wiring portions 12A2 is provided on the lower surface of the frame portion 11N. The second wiring portion 12A2 may be provided on an outer surface different from the lower surface 11B of the package 10.

When the base 11 is divided into two regions by a virtual line passing through the lateral surface 11H of the first step portion 11F1 and parallel to the lateral surface 11H in a top view, the base 11 includes the one or more second wiring portions 12A2 provided on the lower surface 11B of the base 11 in a region including the upper surface 11G of the first step portion 11F1.

When the base 11 is divided into two regions by a virtual line passing through the lateral surface 11H of the second step portion 11F2 and parallel to the lateral surface 11H in a top view, the base 11 includes the one or more second wiring portions 12A2 provided on the lower surface 11B of the base 11 in a region including the upper surface 11G of the second step portion 11F2.

In the base 11, one or each of the first wiring portions 12A1 is electrically connected to the second wiring portion 12A2. The one or more first wiring portions 12A1 are electrically connected to the mutually different second wiring portions 12A2.

The base 11 includes a bonding pattern 13A. The bonding pattern 13A is provided on the second upper surface 11C. The bonding pattern 13A is provided annularly. The bonding pattern 13A is provided in a rectangular and annular shape. In a top view, the first upper surface 11A is surrounded by the bonding pattern 13A.

The base 11 can be formed using a ceramic as a main material, for example. Examples of the ceramic as the main material of the base 11 include aluminum nitride, silicon nitride, aluminum oxide, and silicon carbide.

The main material as used herein refers to a material that accounts for the greatest proportion of a target formed product in terms of mass or volume. When a target formed product is formed of a single material, the material is the main material. In other words, when a certain material is the main material, the proportion of the material may be 100%.

The base 11 may be formed using a base member and a frame member formed of main materials different from each other. The base member can be formed using a main material having excellent heat dissipation, for example, a metal or a composite containing a metal, graphite, or diamond. Examples of the metal as the main material of the base member include copper, aluminum, and iron. Examples of the composite containing the metal as the main material of the base member include copper-molybdenum and copper-tungsten. The frame member can be formed using, as a main material, for example, any of the ceramics exemplified above as the main material of the base 11.

The wiring portion 12A can be formed using a metal material as a main material, for example. Examples of the metal material as the main material of the wiring portion 12A include single-component metals, such as Cu, Ag, Ni, Au, Ti, Pt, Pd, Cr, and W, and alloys containing any of these metals. The wiring portion 12A can be constituted by one or more metal layers, for example.

The bonding pattern 13A can be formed using a metal material as a main material, for example. Examples of the metal material as the main material of the bonding pattern 13A include single-component metals, such as Cu, Ag, Ni, Au, Sn, Ti, and Pd, and alloys containing any of these metals. The bonding pattern 13A can be constituted by one or more metal layers, for example.

The lid body 14 has the upper surface 14A and the lower surface 14B. The lid body 14 also has one or more lateral surfaces 14C. The lid body 14 is formed of a flat plate with a rectangular parallelepiped shape. The lid body 14 does not necessarily have a rectangular parallelepiped shape.

An outer edge shape of the upper surface 14A of the lid body 14 is rectangular. This rectangle can include long sides and short sides. This rectangle includes a first side 14A1, a second side 14A2, a third side 14A3, and a fourth side 14A4. The second side 14A2 is parallel to the first side 14A1. The third side 14A3 is orthogonal to the first side 14A1. The fourth side 14A4 is parallel to the third side 14A3. The first side 14A1 is a long side of this rectangle.

An outer edge shape of the lower surface 14B of the lid body 14 is rectangular. This rectangle can include long sides and short sides. This rectangle includes a first side 14B1, a second side 14B2, a third side 14B3, and a fourth side 14B4. The second side 14B2 is parallel to the first side 14B1. The third side 14B3 is orthogonal to the first side 14B1. The fourth side 14B4 is parallel to the third side 14B3. The first side 14B1 is a long side of this rectangle.

The first side 14A1 of the upper surface 14A and the first side 14B1 of the lower surface 14B are an upper side and a lower side of the one lateral surface 14C common thereto. The outer edge shape of the upper surface 14A and an inner edge shape of the lower surface 14B are the same shape. The term “same shape” used here allows for a difference within ±25 μm.

The lid body 14 is bonded to the base 11. The lower surface 14B of the lid body 14 is bonded to the second upper surface 11C of the base 11. The lid body 14 is bonded to the bonding pattern 13A of the base 11. The lid body 14 is bonded to the base 11 via an adhesive.

The lid body 14 includes the bonding pattern 14D. The bonding pattern 14D is provided on the lower surface 14B of the lid body 14. The bonding pattern 14D has a rectangular and annular shape. The bonding pattern 14D of the lid body 14 and the bonding pattern 13A of the base 11 are bonded to the base 11 via an adhesive. As this adhesive, for example, AuSn solder can be adopted.

The outer edge shape of the lower surface of the lid body 14 is smaller than the outer frame of the second upper surface 11C of the base 11 and larger than the inner frame of the second upper surface 11C. An outer edge shape of the rectangular and annular region of the bonding pattern 14D is smaller than the outer frame of the second upper surface 11C of the base 11 and larger than the inner frame of the second upper surface 11C. An inner edge shape of the rectangular and annular region of the bonding pattern 14D is the same as or smaller than the inner frame of the second upper surface 11C.

An outer edge shape of the bonding pattern 14D is rectangular. This rectangle includes a first side 14D1, a second side 14D2, a third side 14D3, and a fourth side 14D4 as outer edge sides. The second side 14D2 is parallel to the first side 14D1. The third side 14D3 is orthogonal to the first side 14D1. The fourth side 14D4 is parallel to the third side 14D3.

The first side 14D1 of the bonding pattern 14D is positioned closer to the first side 14B1 of the lower surface 14B than the second side 14D2. The second side 14D2 of the bonding pattern 14D is positioned closer to the second side 14B2 of the lower surface 14B than the first side 14D1. The third side 14D3 of the bonding pattern 14D is positioned closer to the third side 14B3 of the lower surface 14B than the fourth side 14D4. The fourth side 14D4 of the bonding pattern 14D is positioned closer to the fourth side 14B4 of the lower surface 14B than the third side 14D3.

An inner edge shape of the bonding pattern 14D is rectangular. This rectangle shape includes a first side 14D5, a second side 14D6, a third side 14D7, and a fourth side 14D8 as inner edge sides. The second side 14D6 is parallel to the first side 14D5. The third side 14D7 is orthogonal to the first side 14D5. The fourth side 14D8 is parallel to the third side 14D7.

The first side 14D5 of the bonding pattern 14D is positioned closer to the first side 14B1 of the lower surface 14B than the second side 14D6. The second side 14D6 of the bonding pattern 14D is positioned closer to the second side 14B2 of the lower surface 14B than the first side 14D5. The third side 14D7 of the bonding pattern 14D is positioned closer to the third side 14B3 of the lower surface 14B than the fourth side 14D8. The fourth side 14D8 of the bonding pattern 14D is positioned closer to the fourth side 14B4 of the lower surface 14B than the third side 14D7.

A distance from the first side 14D1 of the outer edge to the first side 14D5 of the inner edge of the bonding pattern 14D is the same as a distance from the second side 14D2 of the outer edge to the second side 14D6 of the inner edge. The term “same” used here allows for a difference within ±20 μm. In the present description, the term “distance” refers to the shortest distance unless otherwise specified.

A distance from the third side 14D3 of the outer edge to the third side 14D7 of the inner edge of the bonding pattern 14D is the same as a distance from the fourth side 14D4 of the outer edge to the fourth side 14D8 of the inner edge. The term “same” used here allows for a difference within ±20 μm.

The distance from the first side 14D1 of the outer edge to the first side 14D5 of the inner edge of the bonding pattern 14D is the same as the distance from the third side 14D3 of the outer edge to the third side 14D7 of the inner edge. The term “same” used here allows for a difference within ±20 μm.

A virtual straight line passing through a center of the first side 14B1 of the lower surface 14B of the lid body 14 and orthogonal to the first side 14B1 includes a first line segment and a second line segment overlapping the bonding pattern 14D in a bottom view. The first line segment and the second line segment have the same length. This can balance bonding force on the first side 14D1 side and bonding force on the second side 14D2 side when the lid body 14 is bonded to the base 11 and execute stable bonding processing.

The outer edge shape of the bonding pattern 14D is smaller than a shape of the outer frame of the base 11. The bonding pattern 14D of the lid body 14 is aligned not with the outer frame but with an inner frame of the base 11. This makes it easy to adjust an outer edge shape of the lid body 14.

In a bottom view, a distance from the rectangular and annular region of the bonding pattern 14D to the first side 14B1 of the lower surface 14B is greater than a distance from this region to the second side 14B2 of the lower surface 14B. In a bottom view, a distance from the first side 14D1 of the outer edge of the bonding pattern 14D to the first side 14B1 of the lower surface 14B is greater than a distance from the second side 14D2 of the outer edge of the bonding pattern 14D to the second side 14B2 of the lower surface 14B. This can implement, even when the disposed position of the lid body 14 on the first side 14D1 side and the disposed position of the lid body 14 on the second side 14D2 side with respect to the base 11 are asymmetric, the bonding pattern 14D in which the bonding on the first side 14D1 side and the bonding on the second side 14D2 side are balanced in accordance with the asymmetry.

In a bottom view, the distance from the rectangular and annular region of the bonding pattern 14D to the first side 14B1 of the lower surface 14B is greater than a distance from this region to the third side 14B3 of the lower surface 14B. In a bottom view, the distance from the first side 14D1 of the outer edge of the bonding pattern 14D to the first side 14B1 of the lower surface 14B is greater than a distance from the third side 14D3 of the outer edge of the bonding pattern 14D to the third side 14B3 of the lower surface 14B.

In a bottom view, the distance from the rectangular and annular region of the bonding pattern 14D to the first side 14B1 of the lower surface 14B is greater than a distance from this region to the fourth side 14B4 of the lower surface 14B. In a bottom view, the distance from the first side 14D1 of the outer edge of the bonding pattern 14D to the first side 14B1 of the lower surface 14B is greater than a distance from the fourth side 14D4 of the outer edge of the bonding pattern 14D to the fourth side 14B4 of the lower surface 14B.

In a bottom view, the distance from the first side 14D1 of the outer edge of the bonding pattern 14D to the first side 14B1 of the lower surface 14B is in a range from 300 μm to 800 μm. In a bottom view, the distance from the second side 14D2 of the outer edge of the bonding pattern 14D to the second side 14B2 of the lower surface 14B is greater than 0 μm and 200 μm or less. In a bottom view, the distance from the first side 14D1 of the outer edge of the bonding pattern 14D to the first side 14B1 of the lower surface 14B is in a range from three times to 10 times the distance from the second side 14D2 of the outer edge of the bonding pattern 14D to the second side 14B2 of the lower surface 14B.

The lid body 14 has the buffer line pattern 14E. The buffer line pattern 14E is provided on the lower surface 14B of the lid body 14. The buffer line pattern 14E includes a buffer line 14E1 that is a straight line at a predetermined distance from the first side 14D1 of the outer edge of the bonding pattern 14D. The buffer line pattern 14E is provided between the first side 14B1 of the lower surface 14B and the first side 14D1 of the outer edge of the bonding pattern 14D. Accordingly, it can be confirmed that the first side 14B1 that is the outer edge of the lower surface 14B of the lid body 14 is separated from the first side 14D1 that is the outer edge of the bonding pattern 14D1 by a predetermined distance or more.

Having the predetermined distance on the basis of the buffer line pattern 14E can confirm that a necessary buffer is left between the outer edge of the bonding pattern 14D and the outer edge of the lower surface 14B of the lid body 14 in order to leave an application region of the adhesive in the bonding of the lid body 14 and the optical member 70, for example, and achieve stable bonding processing.

In the lid body 14, the buffer line pattern 14E is not provided between the second side 14B2 of the lower surface 14B and the second side 14D2 of the outer edge of the bonding pattern 14D. In a bottom view, the distance from the second side 14B2 of the lower surface 14B to the second side 14D2 of the outer edge of the bonding pattern 14D is smaller than a predetermined distance from the first side 14D1 of the outer edge of the bonding pattern 14D to the buffer line 14E1.

The lid body 14 is bonded to the base 11 such that the first side 14B1 of the lower surface 14B of the lid body 14 is disposed closer to the first side 11C1 of the outer edge of the base 11 than the second side 14B2 of the lower surface 14B. The lid body 14 is bonded to the base 11 such that the second side 14B2 of the lower surface 14B of the lid body 14 is disposed closer to the second side 11C2 of the outer edge of the base 11 than the first side 14B1 of the lower surface 14B.

The lid body 14 is bonded to the base 11 with a distance from the second side 11C2 of the outer edge of the base 11 to the second side 14B2 of the lower surface 14B of the lid body 14 being greater than a distance from the first side 11C1 of the outer edge of the base 11 to the first side 14B1 of the lower surface 14B of the lid body 14 in a top view. Adopting the lid body 14 satisfying this condition can reduce a size of the lid body 14 and improve production efficiency. The reduction in size of the lid body 14 also leads to a reduction in weight of the lid body 14, making it possible to achieve a reduction in weight of the light-emitting device 1.

A difference between the distance from the second side 11C2 of the outer edge of the base 11 to the second side 14B2 of the lower surface 14B of the lid body 14 and the distance from the first side 11C1 of the outer edge of the base 11 to the first side 14B1 of the lower surface 14B of the lid body 14 is 300 μm or greater. Alternatively, this difference may be 500 μm or greater. Alternatively, this difference may be 600 μm or greater. The larger this difference is, the more the difference contributes to the size reduction of the lid body 14.

In a top view, an outer edge of the lower surface 14B of the lid body 14 is above the second upper surface 11C of the base 11. Thus, with the lid body 14 bonded to the base 11, a closed space is formed inside the package 10. It can be said that the distance from the second side 11C2 of the outer edge of the base 11 to the second side 14B2 of the lower surface 14B of the lid body 14 is smaller than a distance from the second side 11C2 of the outer edge of the base 11 to the second side 11C6 of the inner edge of the base 11.

The lid body 14 is bonded to the base 11 with a distance from the third side 11C3 of the outer edge of the base 11 to the third side 14B3 of the lower surface 14B of the lid body 14 being greater than the distance from the first side 11C1 of the outer edge of the base 11 to the first side 14B1 of the lower surface 14B of the lid body 14 in a top view. By adopting the lid body 14 satisfying this condition, it is possible to reduce the size of the lid body 14.

The lid body 14 is bonded to the base 11 with a distance from the fourth side 11C4 of the outer edge of the base 11 to the fourth side 14B4 of the lower surface 14B of the lid body 14 being greater than the distance from the first side 11C1 of the outer edge of the base 11 to the first side 14B1 of the lower surface 14B of the lid body 14 in a top view. By adopting the lid body 14 satisfying this condition, it is possible to reduce the size of the lid body 14.

The lid body 14 has transmissivity to transmit light. The description “transmissivity” as used here means that the transmittance for light incident on the lid body 14 is 80% or greater. The lid body 14 may partially include a non-light transmitting region (a region with no transmissivity).

The lid body 14 can be formed using glass as a main material, for example. The lid body 14 can also be formed using sapphire as a main material, for example. The lid body 14 can be formed by providing the bonding pattern 14D and the buffer line pattern 14E on a light-transmissive member formed using the main material.

The bonding pattern 14D can be formed using a metal material as a main material, for example. Examples of the metal material as the main material of the bonding pattern 13A include single-component metals, such as Cu, Ag, Ni, Au, Sn, Ti, and Pd, and alloys containing any of these metals. The bonding pattern 14D can be constituted by one or more metal layers, for example. The buffer line pattern 14E can be formed using the same material as that of the bonding pattern 14D.

### Light-Emitting Element 20

The light-emitting element 20 has an upper surface 21A, a lower surface 21B, and a plurality of lateral surfaces 21C. A shape of the upper surface 21A is rectangular. This rectangle is a rectangle including long sides and short sides. An outer shape of the light-emitting element 20 in a top view is rectangular. This rectangle is a rectangle including long sides and short sides. The shape of the upper surface 21A and the outer shape of the light-emitting element 20 in a top view are not limited thereto.

The light-emitting element 20 has a light exit surface 22 that emits light. For example, the lateral surface 21C can serve as the light exit surface 22. The lateral surface 21C serving as the light exit surface 22 meets a short side of the upper surface 21A. For example, the upper surface 21A can serve as the light exit surface 22. The light-emitting element 20 has one or more of the light exit surfaces 22.

As the light-emitting element 20, for example, a light-emitting element that emits blue light can be employed. As the light-emitting element 20, for example, a light-emitting element that emits green light can be employed. As the light-emitting element 20, for example, a light-emitting element that emits red light can be employed. As the light-emitting element 20, a light-emitting element that emits light of another color or another wavelength may be employed.

Here, blue light refers to light having a light emission peak wavelength within a range from 420 nm to 494 nm. Green light refers to light having a light emission peak wavelength within a range from 495 nm to 570 nm. Red light refers to light having a light emission peak wavelength within a range from 605 nm to 750 nm.

Examples of the light-emitting element 20 that emits blue light or the light-emitting element 20 that emits green light include a light-emitting element containing a nitride semiconductor. A GaN-based semiconductor, such as GaN, InGaN, or AlGaN, can be employed as the nitride semiconductor. Examples of the light-emitting element 20 that emits red light include a light-emitting element containing an InAlGaP-based semiconductor, a GaInP-based semiconductor, or a GaAs-based semiconductor, such as GaAs or AlGaAs.

As the light-emitting element 20, for example, a semiconductor laser element can be employed. As the light-emitting element 20, a single-emitter semiconductor laser element constituted by one emitter can be employed. As the light-emitting element 20, a multi-emitter semiconductor laser element constituted by a plurality of emitters can be employed. The light-emitting element 20 is not limited to a semiconductor laser element, and may be, for example, a light-emitting diode.

Here, a semiconductor laser element as an example of the light-emitting element 20 will be described.

The semiconductor laser element emits a directional laser beam. Spreading divergent light is emitted from the light exit surface 22 of the semiconductor laser element. The light emitted from the semiconductor laser element forms a far-field pattern (hereinafter, referred to as an “FFP”) with an elliptical shape in a plane parallel to the light exit surface 22. The FFP indicates a shape or a light intensity distribution of the emitted light at a position spaced apart from the light exit surface of the semiconductor laser element.

Here, light passing through the center of the elliptical shape of the FFP, in other words, light having a peak intensity in the light intensity distribution of the FFP is referred to as light traveling along an optical axis or light passing through an optical axis. Based on the light intensity distribution of the FFP, light having an intensity that is equal to or more than 1/e² with respect to the peak intensity is referred to as a main portion of the light.

The FFP of the light emitted from the semiconductor laser element has an elliptical shape in which the length in a layering direction is greater than that in a direction perpendicular to the layering direction in the plane parallel to the light exit surface 22. The layering direction is a direction in which a plurality of semiconductor layers including an active layer are layered in the semiconductor laser element. The direction perpendicular to the layering direction can also be referred to as a plane direction of the semiconductor layer. A long diameter direction of the elliptical shape of the FFP can also be referred to as a fast axis direction of the semiconductor laser element, and a short diameter direction of the elliptical shape of the FFP can also be referred to as a slow axis direction of the semiconductor laser element.

Based on the light intensity distribution of the FFP, an angle at which light having a light intensity of 1/e² of the peak light intensity spreads is referred to as a divergence angle of light of the semiconductor laser element. Here, the divergence angle of light is indicated as an angle formed by light having the peak light intensity (light passing through an optical axis) and light having a light intensity of 1/e² of the peak light intensity. In some cases, the divergence angle of light can also be determined based on, for example, the light intensity that is half of the peak light intensity, other than being determined based on the light intensity of 1/e² of the peak light intensity. In the present description, the term “divergence angle of light” by itself refers to a divergence angle of light at the light intensity of 1/e² of the peak light intensity.

The divergence angle in the fast axis direction of the light emitted from the semiconductor laser element can be 15 degrees or more and less than 40 degrees. The divergence angle of the light in the slow axis direction can be in a range from more than 0 degrees to 10 degrees. The divergence angle of the light in the fast axis direction is greater than the divergence angle of the light in the slow axis direction.

For example, the divergence angle in the fast axis direction of blue light emitted from the semiconductor laser element can be in a range from 15 degrees to less than 30 degrees, and the divergence angle in the slow axis direction can be in a range from greater than 0 degrees and less than 10 degrees. For example, the divergence angle in the fast axis direction of green light emitted from the semiconductor laser element can be in a range from 15 degrees to less than 30 degrees, and the divergence angle in the slow axis direction can be in a range from greater than 0 degrees and less than 10 degrees. For example, the divergence angle in the fast axis direction of red light emitted from the semiconductor laser element can be in a range from 20 degrees to less than 40 degrees, and the divergence angle in the slow axis direction can be in a range from greater than 0 degrees and less than 10 degrees.

### Submount 30

The submount 30 has an upper surface 31A, a lower surface 31B, and one or more lateral surfaces 31C. It can be said that the upper surface 31A is a mounting surface on which other components are mounted. A shape of the upper surface 31A is rectangular. This rectangle of the upper surface 31A can have short sides and long sides. The shape of the upper surface 31A need not be a rectangle.

An outer shape of the submount 30 in a top view is rectangular. This rectangle of the submount 30 can include short sides and long sides. The outer shape of the submount 30 in a top view need not be rectangular. The submount 30 can have, in a top view, an outer shape having a length in one direction (hereinafter, the direction is referred to as a lateral direction of the submount 30) smaller than a length in a direction (hereinafter, the direction is referred to as a longitudinal direction of the submount 30) perpendicular to the one direction. In the submount 30 illustrated by the drawings, the lateral direction is the same direction as the X direction, and the longitudinal direction is the same direction as the Y direction.

The submount 30 can include a substrate 32A and an upper metal member 32B. The submount 30 can further include a lower metal member 32C. The upper metal member 32B is provided on an upper surface side of the substrate 32A. The lower metal member 32C is provided on a lower surface side of the substrate 32A. The submount 30 further includes a wiring layer 33. The wiring layer 33 is provided on the upper metal member 32B.

The substrate 32A has an insulating property. The substrate 32A is formed of, for example, silicon nitride, aluminum nitride, or silicon carbide. It is preferable to select a ceramic with relatively good heat dissipation (having high thermal conductivity) as a main material of the substrate 32A.

A metal such as copper or aluminum is used as a main material of the upper metal member 32B. The upper metal member 32B includes one or more metal layers. The upper metal member 32B can include a plurality of metal layers formed using different metals as main materials.

A metal such as copper or aluminum is used as the main material of the lower metal member 32C. The lower metal member 32C includes one or more metal layers. The lower metal member 32C can include a plurality of metal layers formed using different metals as main materials.

The wiring layer 33 can be formed using a metal. For example, the wiring layer 33 can be formed using AuSn solder (a metal layer of AuSn).

### Reflective Member 40

The reflective member 40 has a lower surface 41A, and a light-reflective surface 41B that reflects light. The light-reflective surface 41B is inclined with respect to the lower surface 41A. A straight line connecting a lower end and an upper end of the light-reflective surface 41B is inclined with respect to the lower surface 41A. An angle at which the light-reflective surface 41B is inclined with respect to the lower surface 41A is referred to as an inclination angle of the light-reflective surface 41B.

The light-reflective surface 41B is a flat surface. The light-reflective surface 41B may be a curved surface. The inclination angle of the light-reflective surface 41B is 45 degrees. The light-reflective surface 41B need not have an inclination angle of 45 degrees.

As the main material of the reflective member 40, glass, metal, or the like can be used. A heat-resistant material is preferably used as the main material of the reflective member 40. As the main material, for example, a glass such as quartz glass or borosilicate glass (BK7), or a metal such as Al can be used. The reflective member 40 can also be formed using Si as the main material.

When the main material is a reflective material such as Al, the light-reflective surface 41B can be formed of the main material. Instead of forming the light-reflective surface 41B with the main material, a general form of the reflective member 40 may be formed with the main material, and the light-reflective surface 41B may be formed on a surface of the general form. In this case, the light-reflective surface 41B can be formed using, for example, a layer of a metal such as Ag or Al, or a dielectric multilayer film of Ta₂O₅/SiO₂, TiO₂/SiO₂, or Nb₂O₅/SiO₂.

In the light-reflective surface 41B, the reflectance with respect to the peak wavelength of the light with which the light-reflective surface 41B is irradiated is equal to or more than 90%. The reflectance may be equal to or more than 95%. The reflectance may be equal to or more than 99%. The light reflectance is equal to or less than 100% or is less than 100%.

### Protective Element 50

The protective element 50 has an upper surface 51A, a lower surface 51B, and one or more lateral surfaces 51C. A shape of the protective element 50 is a rectangular parallelepiped. The shape of the protective element 50 need not be a rectangular parallelepiped.

The protective element 50 prevents breakage of a specific element (the semiconductor laser element, for example) due to an excessive current flowing through the element. The protective element 50 is, for example, a Zener diode. A Zener diode formed of Si can be used.

### Wiring Line 60

The wiring line 60 is a linear conductive material having bonding portions at both ends. The bonding portions at both ends serve as portions for bonding with other components. The wiring line 60 is used for electrical connection between two components. The wiring line 60 is, for example, a metal wire. The metal used can be, for example, gold, aluminum, silver, or copper.

### Optical Member 70

The optical member 70 has an upper surface 71A, a lower surface 71B, and one or more lateral surfaces 71C. The optical member 70 imparts an optical action to light that is incident on the optical member 70. Examples of the optical action imparted to the light by the optical member 70 include condensing, collimation, diffusion, polarization, diffraction, multiplexing, light guiding, reflection, and wavelength conversion.

The optical member 70 has an optical action surface that imparts the optical action. The upper surface 71A, the lower surface 71B, or the lateral surface 71C can serve as the optical action surface. Alternatively, the optical action surface may be provided at a position different from the upper surface 71A, the lower surface 71B, or the lateral surface 71C. For example, the optical action surface may be formed not on a surface of the optical member 70 but on an inner side of the optical member 70.

The optical member 70 can have one or more lens surfaces 71D. The lens surface 71D is the optical action surface of the optical member 70. The optical member 70 having the lens surface 71D may be referred to as a lens member. Light passing through the lens surface 71D and emitted from the optical member 70 is imparted an optical action of condensing, diffusion, or collimation by the optical member 70. For example, the optical member 70 is a collimating lens that collimates light that is incident on the optical member 70 and emits the collimated light.

One or each of the lens surfaces 71D is provided on the upper surface 71A side. The lens surface 71D may be provided on the lower surface 71B side. The upper surface 71A and the lower surface 71B are flat surfaces. The one or each of the lens surfaces 71D meets the upper surface 71A. In a top view, the one or each of the lens surfaces 71D is surrounded by the upper surface 71A.

An outer shape of the optical member 70 in a top view is rectangular. The outer shape of the optical member 70 in a top view need not be rectangular. The lower surface 71B is a flat surface. The lens surface 71D is not formed on the lower surface 71B side of the optical member 70.

An outer edge shape of the lower surface 71B of the optical member 70 is rectangular. This rectangle can include long sides and short sides. This rectangle includes a first side 71B1, a second side 71B2, a third side 71B3, and a fourth side 71B4. The second side 71B2 is parallel to the first side 71B1. The third side 71B3 is orthogonal to the first side 71B1. The fourth side 71B4 is parallel to the third side 71B3. The first side 71B1 is a long side of this rectangle.

In the optical member 70, a distance from the first side 71B1 of the optical member 70 to the one or more lens surfaces 71D is the same as a distance from the second side 71B2 of the optical member 70 to the one or more lens surfaces 71D in a top view. The term “same” used here allows for a difference within ±60 μm.

In the optical member 70, a distance from the third side 71B3 of the optical member 70 to the one or more lens surfaces 71D is the same as a distance from the fourth side 71B4 of the optical member 70 to the one or more lens surfaces 71D in a top view. The term “same” used here allows for a difference within ±60 μm.

In the optical member 70, a maximum width of the one or more lens surfaces 71D in a direction orthogonal to the first side 71B1 of the optical member 70 is 65% or more of a maximum width of the optical member 70 in a top view. Alternatively, the maximum width of the former is 70% or more of the maximum width of the latter. Alternatively, the maximum width of the former is 75% or more of the maximum width of the latter. As a ratio of the width occupied by the lens surface 71D in the optical member 70 increases, a ratio of margins other than the lens decreases, which contributes to a reduction in size or weight of the optical member 70.

In the optical member 70, a portion overlapping the lens surface 71D in a top view is a lens portion 72A. In the optical member 70, a portion overlapping the upper surface 71A in a top view is a non-lens portion 72B. The lens portion 72A overlaps the one or more of lens surfaces 71D in a top view. The non-lens portion 72B does not overlap the one or more lens surfaces 71D in a top view. The lower surface 71B includes a region constituting a lower surface of one or each of the lens portions 72A and a region constituting a lower surface of the non-lens portion 72B.

The optical member 70 can have a plurality of the lens surfaces 71D formed continuously in one direction. A direction in which the plurality of lens surfaces 71D are aligned in a top view is referred to as a coupling direction of the lenses. In the illustrated optical member 70, the coupling direction is the same direction as the X direction.

The plurality of lens surfaces 71D are formed such that vertices of the respective lens surfaces 71D are provided on one straight line. A virtual straight line connecting the respective vertices is parallel to the lower surface 71B of the optical member 70. The term “parallel” used here allows for a difference within ±5 degrees.

Curvatures of two or more lens surfaces 71D, that is, some or all of the plurality of lens surfaces 71D can be the same. The plurality of lens surfaces 71D can all have the same curvatures.

The optical member 70 has transmissivity. In the optical member 70, the transmittance with respect to the peak wavelength of light incident on the optical member 70 is equal to or more than 80%. The optical member 70 may include a region having transmissivity and a region having no transmissivity (hereinafter, referred to as a non-light transmitting region). In the non-light-transmitting region, the transmittance with respect to the peak wavelength of light incident on the optical member 70 is equal to or less than 50%. The optical member 70 can be formed using, for example, glass such as BK7.

### Bonding Member 80

The bonding member 80 is formed by curing an adhesive. The adhesive is used to bond a plurality of components. For example, an ultraviolet curable resin adhesive can be used as the adhesive. For example, a thermosetting resin adhesive can be used for the adhesive. As the ultraviolet curable resin adhesive, an epoxy resin or an acrylate resin adhesive can be used. As the thermosetting resin adhesive, an epoxy resin or a silicone resin adhesive can be used.

Next, the light-emitting device 1 will be described.

### Light-Emitting Device 1

In the light-emitting device 1, the one or more light-emitting elements 20 are arranged in the internal space of the package 10. The one or more light-emitting elements 20 are arranged on the first upper surface 11A of the base 11. One or each of the light-emitting elements 20 is arranged on the first upper surface 11A via the submount 30.

One or each of the light-emitting elements 20 emits light in a predetermined direction from the light exit surface 22. Light passing through the optical axis travels in this predetermined direction from the light exit surface 22 of one or each of the light-emitting elements 20. The predetermined direction is, for example, the positive direction of Y of the light-emitting device 1 illustrated.

The first side 11C5 of the inner edge of the base 11 is positioned away from the light-emitting element 20 in the positive direction of Y. The second side 11C6 of the inner edge of the base 11 is positioned away from the light-emitting element 20 in the negative direction of Y. The third side 11C7 of the inner edge of the base 11 is positioned away from the light-emitting element 20 in the negative direction of X. The fourth side 11C8 of the inner edge of the base 11 is positioned away from the light-emitting element 20 in the positive direction of X.

In the illustrated light-emitting device 1, the first side 11C1 of the outer edge of the base 11 is parallel to the X direction. The first side 11C5 of the inner edge of the base 11 is parallel to the X direction. The third side 11C3 of the outer edge of the base 11 is parallel to the Y direction. The third side 11C7 of the inner edge of the base 11 is parallel to the Y direction. The term “parallel” used here allows for a difference within ±3 degrees.

In the illustrated light-emitting device 1, the first side 14A1 of the upper surface 14A of the lid body 14 is parallel to the X direction. The first side 14B1 of the lower surface 14B of the lid body 14 is parallel to the X direction. The third side 14A3 of the upper surface 14A of the lid body 14 is parallel to the Y direction. The third side 14B3 of the lower surface 14B of the lid body 14 is parallel to the Y direction. The term “parallel” used here allows for a difference within ±3 degrees.

In the illustrated light-emitting device 1, the first side 11D1 of the outer edge of the bonding pattern 14D is parallel to the X direction. The first side 11D5 of the inner edge of the bonding pattern 14D is parallel to the X direction. The third side 11D3 of the outer edge of the bonding pattern 14D is parallel to the Y direction. The third side 11D7 of the inner edge of the bonding pattern 14D is parallel to the Y direction. The buffer line 14E1 is parallel to the X direction. The term “parallel” used here allows for a difference within ±3 degrees.

The light-emitting device 1 may include a plurality of the light-emitting elements 20. The plurality of light-emitting elements 20 are disposed side by side in one direction. The plurality of light-emitting elements 20 can be disposed side by side in a second direction orthogonal to a first direction in a top view. The plurality of light-emitting elements 20 each emit light in the first direction from the light exit surface 22. The plurality of light-emitting elements 20 are arranged side by side spaced apart at equal intervals in the second direction.

In the light-emitting device 1, the one or more submounts 30 are arranged in the internal space of the package 10. The one or more submounts 30 are arranged on the first upper surface 11A of the base 11. The submount 30 has a width in the first direction larger than a width in the second direction.

The light-emitting device 1 may include a plurality of the submounts 30. In the light-emitting device 1, one submount 30 corresponds to one light-emitting element 20. The plurality of submounts 30 are disposed side by side in the second direction.

In the light-emitting device 1, the one or more reflective members 40 are arranged in the internal space of the package 10. The one or more reflective members 40 are arranged on the first upper surface 11A of the base 11. The one or more reflective members 40 are disposed at positions away from the one or more light-emitting elements 20 in the first direction. In a top view, the one or more reflective members 40 are disposed between the one or more light-emitting elements 20 and the first side 11C5 of the inner edge of the base 11.

The light emitted from the one or more light-emitting elements 20 is reflected by the one or more reflective members 40. One or each of the reflective members 40 reflects 90% or more of the light from the light-emitting element 20 emitted to the light-reflective surface 41B. Light traveling in the first direction from the light exit surface 22 of the light-emitting element 20 is reflected upward by the light-reflective surface 41B.

The light-emitting device 1 may include a plurality of the reflective members 40. In the light-emitting device 1, one reflective member 40 corresponds to one light-emitting element 20. The plurality of reflective members 40 are disposed side by side in the second direction.

In the light-emitting device 1, the one or more protective elements 50 are arranged in the internal space of the package 10. The one or more protective elements 50 are arranged on the first upper surface 11A of the base 11. One or each of the protective elements 50 is arranged on the first upper surface 11A via the submount 30. The one or each of the protective elements 50 protects the light-emitting element 20.

In one or each of the submounts 30, the light-emitting element 20 and the protective element 50 are mounted on the upper surface 31A of the submount 30. The light-emitting element 20 is arranged on the wiring layer 33 of the submount 30. The protective element 50 is arranged on the wiring layer 33 of the submount 30. The protective element 50 may be arranged on the same wiring layer 33 as the wiring layer 33 on which the light-emitting element 20 is arranged. That is, one wiring layer 33 can be provided with a region in which the light-emitting element 20 is arranged and a region in which the protective element 50 is arranged.

In the light-emitting device 1, the one or more light-emitting elements 20 are provided in the internal space of the package 10. The plurality of wiring lines 60 include the wiring line 60 bonded to the first wiring portion 12A1. The plurality of wiring lines 60 include the wiring line 60 bonded to the first wiring portion 12A1 provided to the upper surface 11G of the first step portion 11F1, and the wiring line 60 bonded to the first wiring portion 12A1 provided to the upper surface 11G of the second step portion 11F2.

The plurality of wiring lines 60 provided to the light-emitting device 1 include two or more of wiring lines 60 provided to electrically connect the one or more light-emitting elements 20 to the package 10. Thus, the one or more light-emitting elements 20 are electrically connected to the package 10.

The plurality of wiring lines 60 provided to the light-emitting device 1 include two or more wiring lines 60 provided to electrically connect the one or more protective elements 50 to the package 10. Thus, the one or more protective elements 50 are electrically connected to the package 10.

In the light-emitting device 1, the optical member 70 is fixed to the package 10. The optical member 70 is bonded to the lid body 14. The lower surface 71B of the optical member 70 is bonded to the upper surface 14A of the lid body 14. The optical member 70 is bonded to the lid body 14 via an adhesive. This adhesive is interposed between the upper surface 14A of the lid body 14 and the lower surface 71B of the optical member 70. This adhesive is cured to form the bonding member 80. The one or more bonding members 80 bond the lid body 14 and the optical member 70.

The light emitted from the upper surface of the lid body 14 is incident on the optical member 70. The light emitted from the upper surface of the lid body 14 is incident on the optical action surface 71D and is provided with an optical action. The light provided with an optical action and is emitted from the optical member 70.

The light emitted from the one or more light-emitting elements 20 passes through the one or more lens surfaces 71D. With the light passing through the one more lens surfaces 71D, collimated light is emitted from the optical member 70, for example. The light emitted from the optical member 70 can be referred to as light emitted from the light-emitting device 1.

The optical member 70 is bonded to the base 11 such that the first side 71B1 of the lower surface 71B is disposed closer to the first side 11C1 of the outer edge of the base 11 than the second side 71B2 of the lower surface 71B. The optical member 70 is bonded to the base 11 such that the second side 71B2 of the lower surface 71B is disposed closer to the second side 11C2 of the outer edge of the base 11 than the first side 71B1 of the lower surface 71B.

In the illustrated light-emitting device 1, the first side 71B1 of the optical member 70 is parallel to the X direction. The third side 71B3 of the optical member 70 is parallel to the Y direction. The term “parallel” used here allows for a difference within ±3 degrees.

The one or more bonding members 80 are provided in a region including the vicinities of four corners of the outer edge of the rectangle of the lower surface 71B of the optical member 70 in a top view. Accordingly, the adhesive is provided mainly on the non-lens portion 72B, making it possible to prevent the bonding member 80 from interfering with light passing through the lens surface 71D.

It can be said that the one or more bonding members 80 are provided on the lower surface 71B of the optical member 70 in the first region R1 including the vicinity of a first corner E1 that is a corner where the first side 71B1 meets the third side 71B3, the second region R2 including the vicinity of a second corner E2 that is a corner where the second side 71B2 meets the third side 71B3, the third region R3 including the vicinity of a third corner E3 that is a corner where the first side 71B1 meets the fourth side 71B4, and the fourth region R4 including the vicinity of a fourth corner E4 that is a corner where the second side 71B2 meets the fourth side 71B4.

The phrase “region including the vicinity of a corner” as used here does not need to include the corner. In the illustrated light-emitting device 1, the one or more bonding members 80 need not overlap the first corner E1, the second corner E2, the third corner E3, and the fourth corner E4. Alternatively, of the one or more bonding members 80, one or more may overlap the first corner E1, the second corner E2, the third corner E3, and the fourth corner E4.

When a corner of the lower surface 71B of the optical member 70 is machined and sides do not directly meet each other, a point at which extending lines passing through the sides meet each other is defined as the corner, and the region including the vicinity of a corner is identified as the “region including the vicinity of a corner”.

The phrase “vicinity of a corner” of the lower surface 71B of the optical member 70 as used here can be defined as a region of a portion overlapping the lower surface 71B in a region having a circular shape with the corner as a center and a maximum length not overlapping one or more lens surfaces 71D in a top view as a radius. The interpretation of the “vicinity of a corner” is not limited to this definition. For example, the “vicinity of a corner” may be defined as a region of a portion overlapping the lower surface 71B in a region having a circular shape with a length corresponding to ½ of this maximum length as the radius. The “vicinity of the corner” may be defined on the basis of a radius less than ½ of the maximum length.

The one or more bonding members 80 include a first bonding portion provided in the first region R1, a second bonding portion provided in the second region R2, a third bonding portion provided in the third region R3, and a fourth bonding portion provided in the fourth region R4. At these bonding portions, the bonding members 80 forming each bonding portion may be spaced apart from each other.

The one or more bonding members 80 include the first bonding member 81 including the first bonding portion. The one or more bonding members 80 include the second bonding member 82 including the second bonding portion. The one or more bonding members 80 include the third bonding member 83 including the third bonding portion. The one or more bonding members 80 include the fourth bonding member 84 including the fourth bonding portion.

The first bonding member 81, the second bonding member 82, the third bonding member 83, and the fourth bonding member 84 may extend outward of the first region R1, the second region R2, the third region R3, and the fourth region R4, respectively, in a top view.

In a top view, the first bonding member 81 may overlap a portion of the lens surface 71D. In a top view, the second bonding member 82 may overlap a portion of the lens surface 71D. In a top view, the third bonding member 83 may overlap a portion of the lens surface 71D. In a top view, the fourth bonding member 84 may overlap a portion of the lens surface 71D. In a top view, each of the first bonding member 81, the second bonding member 82, the third bonding member 83, and the fourth bonding member 84 overlaps only a portion of one lens surface 71D.

The lens surface 71D overlapping the first bonding member 81 in a top view and the lens surface 71D overlapping the second bonding member 82 in a top view are the same lens surface 71D. The lens surface 71D overlapping the third bonding member 83 in a top view and the lens surface 71D overlapping the fourth bonding member 84 in a top view are the same lens surface 71D. The lens surface 71D overlapping the first bonding member 81 in a top view and the lens surface 71D overlapping the third bonding member 83 in a top view can be different lens surfaces 71D.

In a top view, an apex of the one or each of the lens surfaces 71D is positioned closer to the first side 11C1 than to the second side 11C2 of the outer edge of the base 11. In other words, in one or each of the lens surfaces 71D, a distance from the first side 11C1 of the outer edge of the base 11 to the apex of the lens surface 71D is smaller than a distance from the second side 11C2 of the outer edge of the base 11 to the apex of the lens surface 71D in a top view. As described above, the lens portion 72A of the optical member 70 is disposed closer to the first side 11C1 than the second side 11C2 of the base 11.

The first bonding member 81 includes a first end point EP11 that is an end point on the first side 14A1 side and a second end point EP12 that is an end point on the third side 14A3 side. The first end point EP11 is a point on the first side 14A1 of the lid body 14 and farthest from the first corner E1 in a region where first bonding member 81 overlaps the lid body 14 in a top view. The second end point EP12 is a point on the third side 14A3 of the lid body 14 and farthest from the first corner E1 in a region where the first bonding member 81 overlaps the lid body 14 in a top view.

In a top view, a distance from the second end point EP12 to the one or more lens surfaces 71D is smaller than a distance from the first end point EP11 to the one or more lens surfaces 71D. With the reduction in size of the lid body 14, such a bonding form of the first bonding member 81 is possible.

The third bonding member 83 includes a first end point EP31 that is an end point on the first side 14A1 side and a second end point EP32 that is an end point on the fourth side 14A4 side. The first end point EP31 is a point on the first side 14A1 of the lid body 14 and farthest from the third corner E3 in a region where the third bonding member 83 overlaps the lid body 14 in a top view. The second end point EP32 is a point on the fourth side 14A4 of the lid body 14 and farthest from the third corner E3 in a region where the third bonding member 83 overlaps the lid body 14 in a top view.

In a top view, a distance from the second end point EP32 to the one or more lens surfaces 71D is smaller than a distance from the first end point EP31 to the one or more lens surfaces 71D. With the reduction in size of the lid body 14, such a bonding form of the third bonding member 83 is possible.

The second bonding member 82 includes a first end point EP21 and a second end point EP22 that are end points on the third side 14A3 side. The first end point EP21 is a point on the third side 14A3 of the lid body 14 and farthest from the second corner E2 in a region where the second bonding member 82 overlaps the lid body 14 in a top view. The second end point EP22 is a point on the third side 14A3 of the lid body 14 and closest to the second corner E2 in a region where the second bonding member 82 overlaps the lid body 14 in a top view. The region where the second bonding member 82 overlaps the lid body 14 does not overlap the second side 14A2 of the lid body 14 in a top view.

The fourth bonding member 84 includes a first end point EP41 and a second end point EP42 that are end points on the fourth side 14A4 side. The first end point EP41 is a point on the fourth side 14A4 of the lid body 14 and farthest from the fourth corner E4 in a region where the fourth bonding member 84 overlaps the lid body 14 in a top view. The second end point EP42 is a point on the fourth side 14A4 of the lid body 14 and closest to the fourth corner E4 in a region where the fourth bonding member 84 overlaps the lid body 14 in a top view. The region where the fourth bonding member 84 overlaps the lid body 14 does not overlap the second side 14A2 of the lid body 14 in a top view.

In a top view, a width from the first side 71B1 to the second side 71B2 of the optical member 70 is smaller than a width from the first side 11C1 to the second side 11C2 of the outer edge of the base 11. In a top view, the width from the first side 71B1 to the second side 71B2 of the optical member 70 is smaller than a width from the first side 14A1 to the second side 14A2 of the upper surface 14A of the lid body 14.

In a top view, a width from the third side 71B3 to the fourth side 71B4 of the optical member 70 is smaller than a width from the third side 11C3 to the fourth side 11C4 of the outer edge of the base 11. In a top view, the width from the third side 71B3 to the fourth side 71B4 of the optical member 70 is greater than a width from the third side 14A3 to the fourth side 14A4 of the upper surface 14A of the lid body 14.

In a top view, the one or more bonding members 80 are provided in a region interposed between a virtual straight line parallel to the first side 11C1 of the outer edge of the base 11 and passing through the first side 11C1 and a virtual straight line parallel to the second side 11C6 of the inner edge of the base 11 and passing through the second side 11C6. In a top view, the one or more bonding members 80 are not provided in a region interposed between a virtual straight line parallel to the second side 11C2 of the outer edge of the base 11 and passing through the second side 11C2 and the virtual straight line parallel to the second side 11C6 of the inner edge of the base 11 and passing through the second side 11C6.

In a top view, a ratio of an area of the first bonding member 81 provided in a region interposed between a virtual straight line parallel to the third side 71B3 of the optical member 70 and passing through the third side 71B3 and a virtual straight line parallel to the third side 11C7 of the inner edge of the base 11 and passing through the third side 11C7 to an area where the first bonding member 81 is provided is in a range from 50% to 100%. This ratio is preferably in a range from 50% to 80%. When this ratio is small, a width of the optical member 70 in the direction parallel to the second side 71B2 is likely to be large, and when this ratio is large, a width of the optical member 70 in the direction parallel to the first side 71B1 is likely to be large. Therefore, preferably the first bonding member 81 is adjusted, making this ratio appropriate.

In a top view, a ratio of an area of the third bonding member 83 provided in a region interposed between a virtual straight line parallel to the fourth side 71B4 of the optical member 70 and passing through the fourth side 71B4 and a virtual straight line parallel to the fourth side 11C8 of the inner edge of the base 11 and passing through the fourth side 11C8 to the area of the third bonding member 83 is in a range from 50% to 100%. This ratio is preferably in a range from 50% to 80%.

Desirably, the one or more bonding members 80 do not interfere with the optical path of the light passing through the lens portion 72A, and thus preferably the region where the one or more bonding members 80 overlap the lens portion 72A in the top view is small. In a top view, the distance from the end point EP12 to the one or more lens surfaces 71D is smaller than the distance from the end point EP11 to the one or more lens surfaces 71D. Therefore, by increasing a distance from the third side 71B3 to the fourth side 71B4 of the optical member 70, it is possible to increase an application area of the adhesive on the lower surface 71B of the optical member 70, thereby improving the bonding balance.

In a top view, the width from the first side 71B1 to the second side 71B2 of the optical member 70 is smaller than a width from the first side 14B1 to the second side 14B2 of the lower surface 14B of the lid body 14. In a top view, the width from the third side 71B3 to the fourth side 71B4 of the optical member 70 is greater than a width from the third side 14B3 to the fourth side 14B4 of the lower surface 14B of the lid body 14.

The optical member 70 is fixed to the package 10 with the first side 71B1 of the optical member 70 being positioned between the first side 11C1 of the outer edge and the first side 11C5 of the inner edge of the base 11 and the second side 71B2 of the optical member 70 being positioned between the second side 11C2 of the outer edge and the second side 11C6 of the inner edge of the base 11 in a top view.

The optical member 70 is fixed to the package 10 with the third side 71B3 of the optical member 70 being positioned between the third side 11C3 of the outer edge and the third side 11C7 of the inner edge of the base 11 and the fourth side 71B4 of the optical member 70 being positioned between the fourth side 11C4 of the outer edge and the fourth side 11C8 of the inner edge of the base 11 in a top view.

In a top view, the outer edge of the optical member 70 is included inside the outer edge of the outer frame of the base 11. Causing the lateral surface 71C of the optical member 70 not to protrude laterally from the package 10 can make the optical member 70 less likely to peel off from the package 10 due to external force.

The optical member 70 is fixed to the package 10 with the first side 71B1 of the optical member 70 being positioned between the first side 14A1 of the lid body 14 and the first side 11C5 of the inner edge of the base 11 in a top view. The optical member 70 is fixed to the package 10 with the first side 71B1 of the optical member 70 being positioned between the first side 14B1 of the lid body 14 and the first side 11C5 of the inner edge of the base 11 in a top view. This can leave a region of the adhesive that can be applied to the first side 71B1 side and achieve stable bonding of the optical member 70.

The optical member 70 is fixed to the package 10 with the second side 71B2 of the optical member 70 being positioned between the second side 14A2 of the lid body 14 and the second side 11C6 of the inner edge of the base 11 in a top view. The optical member 70 is fixed to the package 10 with the second side 71B2 of the optical member 70 being positioned between the first side 14B1 of the lid body 14 and the first side 11C5 of the inner edge of the base 11 in a top view.

The optical member 70 is fixed to the package 10 with the third side 71B3 of the optical member 70 being positioned between the third side 11C3 of the outer edge and the third side 11C7 of the inner edge of the base 11 and the fourth side 71B4 of the optical member 70 being positioned between the fourth side 11C4 of the outer edge and the fourth side 11C8 of the inner edge of the base 11 in a top view.

The optical member 70 is fixed to the package 10 with the third side 71B3 of the optical member 70 being positioned between the third side 14A3 of the lid body 14 and the third side 11C3 of the outer edge of the base 11 in a top view. The optical member 70 is fixed to the package 10 with the third side 71B3 of the optical member 70 being positioned between the third side 14B3 of the lid body 14 and the third side 11C3 of the outer edge of the base 11 in a top view.

The optical member 70 is fixed to the package 10 with the fourth side 71B4 of the optical member 70 being positioned between the fourth side 14A4 of the lid body 14 and the fourth side 11C4 of the outer edge of the base 11 in a top view. The optical member 70 is fixed to the package 10 with the fourth side 71B4 of the optical member 70 being positioned between the fourth side 14B4 of the lid body 14 and the fourth side 11C4 of the outer edge of the base 11 in a top view.

The optical member 70 is bonded to the lid body 14 with a distance from the first side 14A1 of the upper surface 14A of the lid body 14 to the one or more lens surfaces 71D being smaller than a distance from the second side 14A2 of the upper surface 14A of the lid body 14 to the one or more lens surfaces 71D in a top view. Thus, the optical member 70 is disposed closer to the first side 14A1 than the second side 14A2 of the upper surface 14A of the lid body 14.

The optical member 70 is bonded to the lid body 14 with a distance from the first side 14B1 of the lower surface 14B of the lid body 14 to the one or more lens surfaces 71D being smaller than a distance from the second side 14B2 of the lower surface 14B of the lid body 14 to the one or more lens surfaces 71D in a top view. Thus, the optical member 70 is disposed closer to the first side 14B1 than the second side 14B2 of the lower surface 14B of the lid body 14. With this arrangement, in the light-emitting device 1 of a small size, the lens surface 71D can be disposed in correspondence with the position of the reflective member 40, for example.

In a top view, the second side 71B2 of the optical member 70 is not positioned between the virtual straight line parallel to the second side 11C2 of the outer edge of the base 11 and passing through the second side 11C2 and the virtual straight line parallel to the second side 11C6 of the inner edge of the base 11 and passing through the second side 11C6, but is positioned between the virtual straight line parallel to the second side 11C6 of the inner edge of the base 11 and passing through the second side 11C6 and a virtual straight line parallel to the first side 11C5 of the inner edge of the base 11 and passing through the first side 11C5.

Although the embodiments according to the present invention have been described above, the light-emitting device according to the present invention is not strictly limited to the light-emitting devices of the embodiments. In other words, the present invention may be achieved without being limited to the external shape or structure of the light-emitting device disclosed by each of the embodiments. The present invention can be applied without requiring all the components being provided. For example, in a case in which some of the components of the light-emitting device disclosed by the embodiments are not stated in the claims, a degree of freedom in design by those skilled in the art such as substitutions, omissions, shape deformations, and material changes is allowed for those components, and then it is specified that the invention stated in the claims is applied to those components.

The light-emitting devices described in the embodiments can be used in a projector. That is, the projector can be said to be one application to which the present invention is applied. The present invention is not limited thereto, and can be used in various applications, such as lighting, exposure, on-vehicle headlights, backlights of head-mounted displays and other displays, and the like.

What is claimed is:

1. A light-emitting device comprising:
a base including
a base portion having a first upper surface, and
a frame portion having a second upper surface positioned above the first upper surface and surrounding the first upper surface in a top view;
a lid body having an upper surface and a lower surface bonded to the second upper surface of the base;
one or more light-emitting elements disposed on the first upper surface of the base; and
a lens member having a lower surface bonded to the upper surface of the lid body, wherein
an outer edge shape of the second upper surface of the base is a rectangle having a first side and a second side parallel to the first side in the top view,
an outer edge shape of the lower surface of the lid body is a rectangle having a first side parallel to the first side of the base and a second side parallel to the first side of the lid body in the top view,
the first side of the lid body is disposed closer to the first side of the base than the second side of the lid body,
the second side of the lid body is disposed closer to the second side of the base than the first side of the lid body,
in the top view, a shortest distance from the second side of the base to the second side of the lid body is greater than a shortest distance from the first side of the base to the first side of the lid body,
the lens member includes a lens portion having one or more lens surfaces and a non-lens portion not overlapping the one or more lens surfaces in the top view,
in the top view, a shortest distance from the first side of the lid body to the one or more lens surfaces is smaller than a shortest distance from the second side of the lid body to the one or more lens surfaces, and
in the top view, a maximum width of the one or more lens surfaces is 65% or more of a maximum width of the lens member in a direction orthogonal to the first side of the base.

2. The light-emitting device according to claim 1, wherein
the lid body has a bonding pattern on the lower surface of the lid body, the bonding pattern having a rectangular and annular shape, and
in a bottom view, a shortest distance from a region having the rectangular and annular shape of the bonding pattern to the first side of the lid body is greater than a shortest distance from the region to the second side of the lid body.

3. The light-emitting device according to claim 2, wherein
the outer edge shape of the second upper surface of the base is a rectangle having a third side orthogonal to the first side of the base and a fourth side parallel to the third side in the top view,
the outer edge shape of the lower surface of the lid body is a rectangle having a third side orthogonal to the first side of the lid body and a fourth side parallel to the third side of the lid body in the top view, and
in the bottom view, the shortest distance from the region having the rectangular and annular shape of the bonding pattern to the first side of the lid body is greater than a shortest distance from the region to the third side of the lid body.

4. The light-emitting device according to claim 3, wherein
in the bottom view, the shortest distance from the region having the rectangular and annular shape of the bonding pattern to the first side of the lid body is greater than a distance from the region to the fourth side of the lid body.

5. The light-emitting device according to claim 2, wherein
in the bottom view, a virtual straight line that passes through a center of the first side of the lid body and is orthogonal to the first side of the lid body includes a first line segment and a second line segment overlapping the bonding pattern, and
the first line segment and the second line segment have the same length.

6. The light-emitting device according to claim 1, further comprising
one or more bonding members that bond the lid body and the lens member, wherein
the lens member has an outer shape that is a rectangle in the top view, and
the one or more bonding members are provided in a region including vicinities of four corners of the rectangle of the lens member in the top view.

7. The light-emitting device according to claim 6, wherein
the outer edge shape of the second upper surface of the base is a rectangle having a third side orthogonal to the first side of the base and a fourth side parallel to the third side in the top view,
the outer edge shape of the lower surface of the lid body is a rectangle having a third side orthogonal to the first side of the lid body and a fourth side parallel to the third side of the lid body in the top view, and
in the top view, a shortest distance from the third side of the base to the third side of the lid body is greater than the shortest distance from the first side of the base to the first side of the lid body.

8. The light-emitting device according to claim 7, wherein
in the top view, a shortest distance from the fourth side of the base to the fourth side of the lid body is greater than the shortest distance from the first side of the base to the first side of the lid body.

9. The light-emitting device according to claim 1, wherein
in the top view,
the outer edge shape of the lower surface of the lid body is a rectangle having a third side orthogonal to the first side of the lid body and a fourth side parallel to the third side of the lid body,
an outer edge shape of the lower surface of the lens member is a rectangle having a first side parallel to the first side of the lid body, a second side parallel to the first side of the lens member, a third side orthogonal to the first side of the lens member, and a fourth side parallel to the third side of the lens member,
a width from the first side to the second side of the lens member is smaller than a width from the first side to the second side of the lid body, and
a width from the third side to the fourth side of the lens member is greater than a width from the third side to the fourth side of the lid body.

10. The light-emitting device according to claim 9, further comprising
one or more bonding members that bond the lid body and the lens member, wherein
the one or more bonding members include a first bonding member provided in a region including a vicinity of a first corner that is a corner where the first side and the third side of the lens member meet each other,
an outer edge shape of the upper surface of the lid body is a rectangle having a first side parallel to the first side of the base, a second side parallel to the first side of the upper surface of the lid body, a third side orthogonal to the first side of the upper surface of the lid body, and a fourth side parallel to the third side of the upper surface of the lid body in the top view,
the first bonding member includes, in a region where the first bonding member overlaps the lid body in the top view, a first end point that is on the first side of the upper surface of the lid body and is farthest from the first corner and a second end point that is on the third side of the lid body and is farthest from the first corner, and
in the top view, a distance from the second end point to the one or more lens surfaces is smaller than a distance from the first end point to the one or more lens surfaces.

11. The light-emitting device according to claim 2, wherein
the lid body has a buffer line pattern on the lower surface of the lid body, the buffer line pattern including a straight line pattern extending parallel to the first side of the lower surface, the straight line pattern being arranged between the first side of the lower surface and the bonding pattern in the bottom view.
